(19) United States
(12) Patent Application Publication
(10) Pub. No.: US 2003/0035281 A1
(43) Pub. Date: Feb. 20, 2003

(54) Shock absorber module

(75) Inventors: Chun-Wei Huang, Taipei (CN); Hung-Yue Chang, Taipei (CN)

Correspondence Address: NIXON PEABODY, LLP, 8180 GREENSBORO DRIVE, SUITE 800, MCLEAN, VA, 22102, US

(73) Assignee: Acer Inc., Taipei Hsien (TW)

(21) Appl. No.: 10/096,836

(22) Filed: Mar. 14, 2002

(30) Foreign Application Priority Data
Aug. 16, 2001 (TW) 090214020

(51) Int. Cl. H05K 7/14; H05K 7/18

(52) U.S. Cl. 361/801

(57) ABSTRACT

The present invention provides a shock absorber module used in a portable computer. The shock absorber module includes a bracket, at least one shock absorber, and a modular housing. The bracket accommodates an electronic device therein. The shock absorber connected to a bottom surface of said bracket provides the electronic device with shock absorbing capability. The modular housing provides a space to accommodate the bracket and the shock absorber. The modular housing is detachably installed in an accommodation slot of the portable computer. The present invention also provides a data processing system including a host system, a display device, an input device, a data storage device, and a shock absorber module as above-mentioned.

### BACKGROUND OF THE INVENTION

1. Field of the Invention

The present invention generally relates to a shock absorber module, and more particularly, to a shock absorber module for hard disc drive used in a portable computer.

2. Description of the Prior Art

A portable computer, due to its convenience and portability, is generally mobilized from place to place. Thus, a portable computer experiences shocks frequently due to mobilization process. These impacts possibly cause the damage to internal devices of the portable computer, and to the data stored in a hard disc drive of the portable computer. Therefore, there is a need to provide a shock absorber module for the portable computer to reduce the damage caused by impact.

In the prior art, Taiwanese patent publication No. 389,364 discloses a hard disc drive structure with shock absorbers for a notebook computer. The hard disc drive structure includes a plurality of shock absorbers and a base fixedly connected to a housing of the portable computer. One end of the shock absorber is connected to the base, and the other end is connected to the bottom of the hard disc drive. Therefore, the hard disc drive is free from damage when the shock absorbers are disposed between the base and the hard disc drive to absorb external impact forces. This design requires a specific hard disc drive made for fitting this purpose and is inconvenient for the replacement of the hard disc drive. Taiwanese patent publication No. 415,618 discloses a detachable retaining device with capability to absorb shock to a hard disc drive. The retaining device includes a housing and at least one shock absorber. The housing accommodates the hard disc drive therein. User can install the housing in a slot of a computer. The shock absorbers are disposed between the slot and the housing, either entirely or at some locations. The front end of the housing includes a latch device. This design involves a complex structure and occupies too much space.

### SUMMARY OF THE INVENTION

The present invention is directed toward a shock absorber module used in a portable computer to prevent internal devices from damage due to impact on the portable computer.

It is one object of the present invention to provide a shock absorber module. The shock absorber module is detachably assembled in a portable computer to strengthen shock absorbing capability of internal devices, and particularly to a data storage device, such as a hard disc drive. The shock absorber module includes a bracket, at least one shock absorber, and a modular housing. The bracket is designed for accommodating an electronic device therein. The shock absorber, which is connected to a bottom surface of the bracket, provides the electronic device with shock absorbing capability. The modular housing provides a space to accommodate the bracket and the shock absorber and is detachably installed in an accommodation slot of the portable computer.

It is another object of the present invention to provide a readily assembled shock absorber module. The bracket of the present invention includes at least one leaf spring for engaging the electronic device with the bracket. The leaf spring substitutes for conventional engaging devices, such as screws, to reduce the number of components and to simplify the assembly process.

It is a further object of the present invention to provide a shock absorber module with capability of electromagnetic interference (EMI) shielding. The bracket of the present invention is made of metal and the leaf spring directly contacts a metal housing of the electronic device, so as to provide electromagnetic interference shielding.

It is yet another object of the present invention to provide a shock absorber module with uncomplicated structure using commercialized shock absorbing materials. The shock absorber of the present invention is made of rubber.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic view illustrating a first embodiment of the shock absorber module according to the present invention;

FIG. 2 is a schematic view illustrating a second embodiment of the shock absorber module of the present invention;

FIG. 3A is a schematic view illustrating a bracket of the first and the second embodiments in FIG. 1 and FIG. 2;

FIG. 3B is a schematic view illustrating a modular housing of the first embodiment in FIG. 1;

FIG. 3C is a schematic view illustrating a modular housing of the second embodiment in FIG. 2; and

FIG. 4 is a schematic view illustrating a data processing system according to the present invention.

### DESCRIPTION OF THE PREFERRED EMBODIMENT

Embodiments of the invention will now be described in greater detail.

In accordance with the present invention, the main aspect of the present invention is to protect a hard disc drive and data stored therein of a portable computer, more particularly of a notebook computer.

According to the standard drop test for hard disc drive in a notebook computer, the hard disc drive should perform well without any data storage loss after the notebook computer is free dropped from a height of 72 cm. The shock absorber module and a data processing system according to the present invention further pass a 94-cm drop test. That is, when the data processing system freely falls from a height of 94 cm, the shock absorber module protects the hard disc drive and the data stored therein from damage.

Moreover, in comparison with the prior art, the present invention achieves the shock absorbing capability with lower cost by reducing the number of components and simplifying the assembly process. The shock absorber module designed in different shape, according to the needs, is more flexible over the prior art.

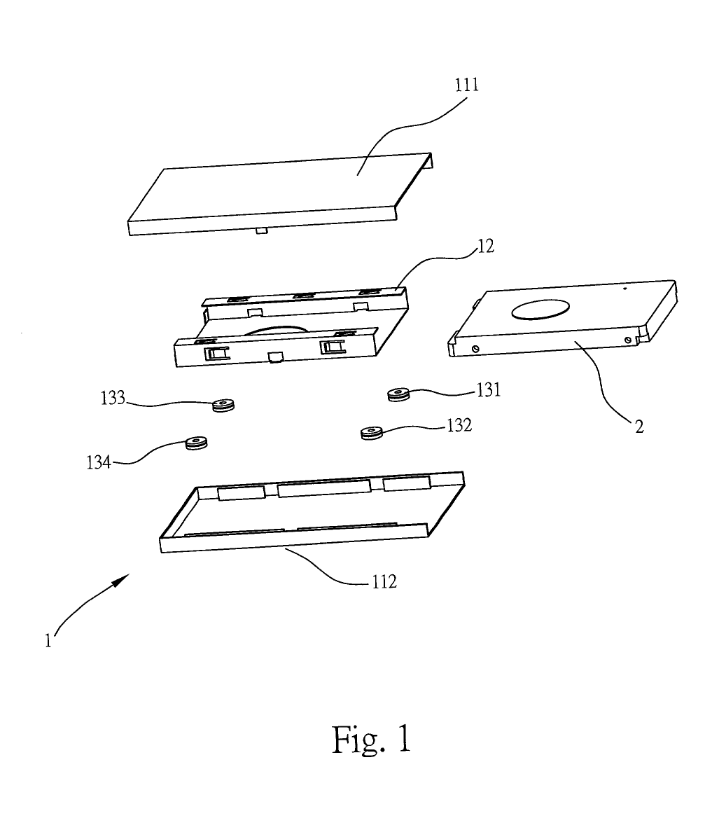

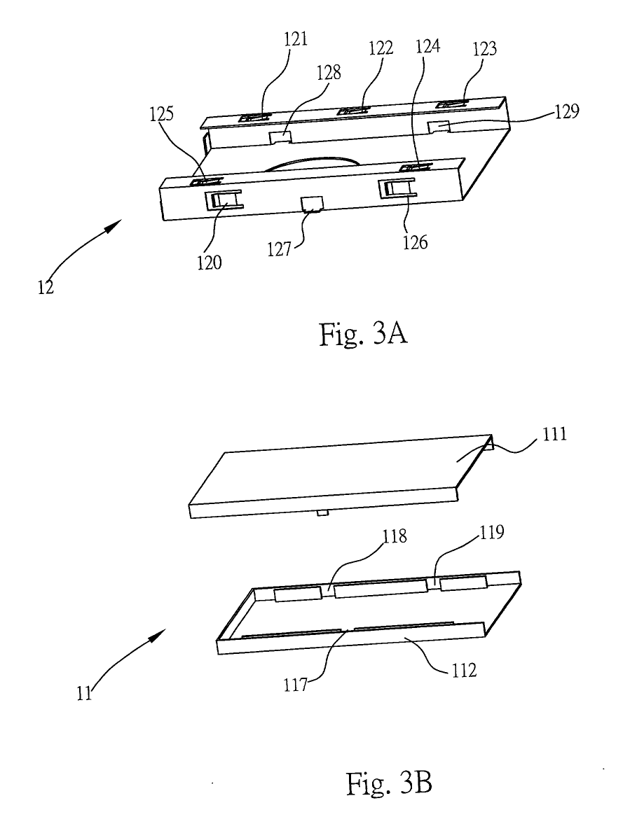

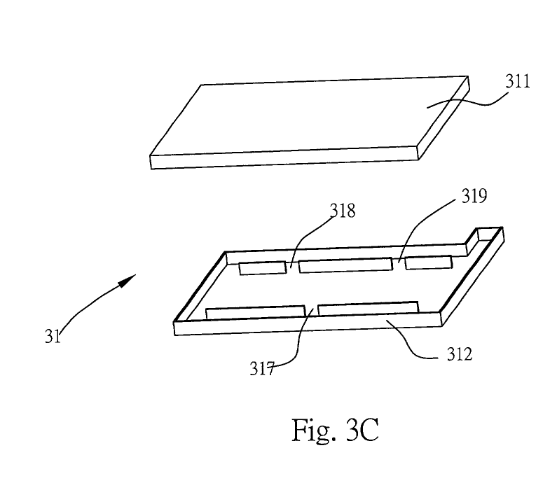

Referring to FIG. 1, the first embodiment of the shock absorber module 1 is illustrated. As shown in FIG. 1, the shock absorber module 1 includes an upper case 111, a bracket 12, a plurality of shock absorbers 131, 132, 133, and 134, and a lower case 112. The upper case 111 and the lower case 112 are assembled together to form a modular housing 11 as illustrated in FIG. 3B.

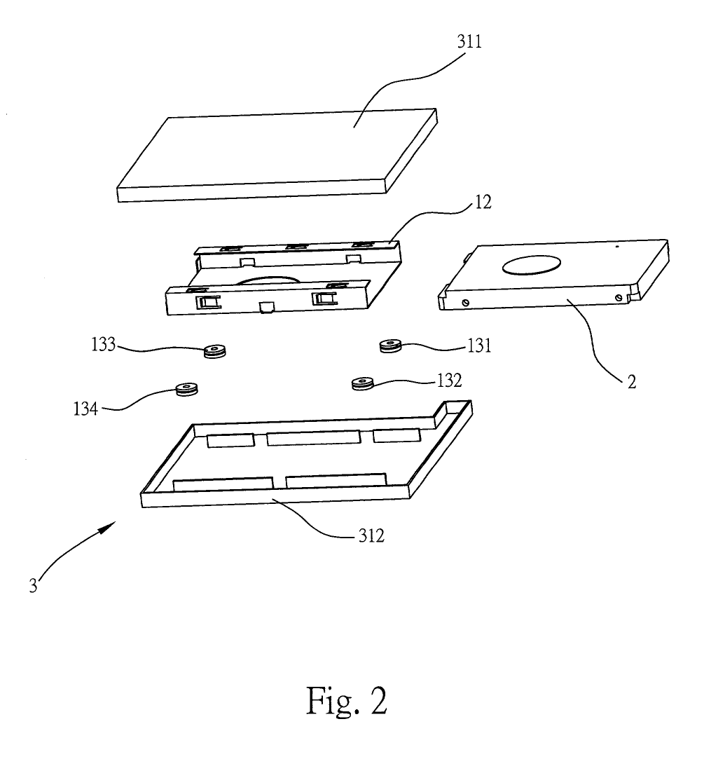

FIG. 2 illustrates the second embodiment of the shock absorber module 3. As shown in FIG. 2, the shock absorber module includes an upper case 311, a bracket 12, a plurality of shock absorbers 131, 132, 133, and 134, and a lower case 312. The upper case 311 and the lower case 312 are assembled together to form a modular housing 31 as illustrated in FIG. 3C.

The shock absorber modules, 1 and 3, are provided in different shape according to the needs, such as the modular housing 11 shown in FIG. 1 and FIG. 3B and the modular housing 31 shown in FIG. 1 and FIG. 3C. That is, the shock absorber module of the present invention is not restricted to be inserted in a specific accommodation slot. In other words, the shock absorber module is interchangeably installed in the same accommodation slot with other modules, such as CD-ROM, DVD-ROM, or battery.

As shown in FIG. 3B and 3C, the modular housing, 11 or 31, provides a space for accommodating the bracket 12 and the shock absorbers 131-134. The bracket 12 accommodates a hard disc drive 2 or other electronic devices therein. The shock absorbers 131-134, which are connected to a bottom surface of the bracket 12, absorb impact on the modular housing 11 or 13 to provide the hard disc drive 2 with shock absorbing capability. The shock absorbers 131-134 are preferably made of rubber, which is easily manufactured and offers a lower cost.

Referring to FIG. 3A, the bracket 12 has a plurality of leaf springs 120, 121, 122, 123, 124, 125, and 126. The leaf springs 120-126 engage the hard disc drive 2 with the bracket 12 to prevent detachment of the hard disc drive 2 from the bracket 12. It is noted that in the present invention the hard disc drive 2 is affixed to the bracket 12 by the leaf springs 120-126, not screws as in the prior art, resulting in the reduction of number of components. Additionally, the bracket 12 is preferably made of metal, and the leaf springs directly contact a metal housing of the hard disc drive 2 to provide electromagnetic interference (EMI) shielding.

Referring to FIGS. 3A, 3B, and 3C, the bracket 12 is further provided with a plurality of protrusions 127, 128, and 129. Correspondingly, the modular housing 11 is provided with a plurality of retaining portions 117, 118, and 119 for accommodating the protrusions 127-129 to restrain movement of the bracket 12. Similarly, the modular housing 31 is provided with a plurality of retaining portions 317, 318, and 319 for accommodating the protrusions 127-129 to restrain movement of the bracket 12.

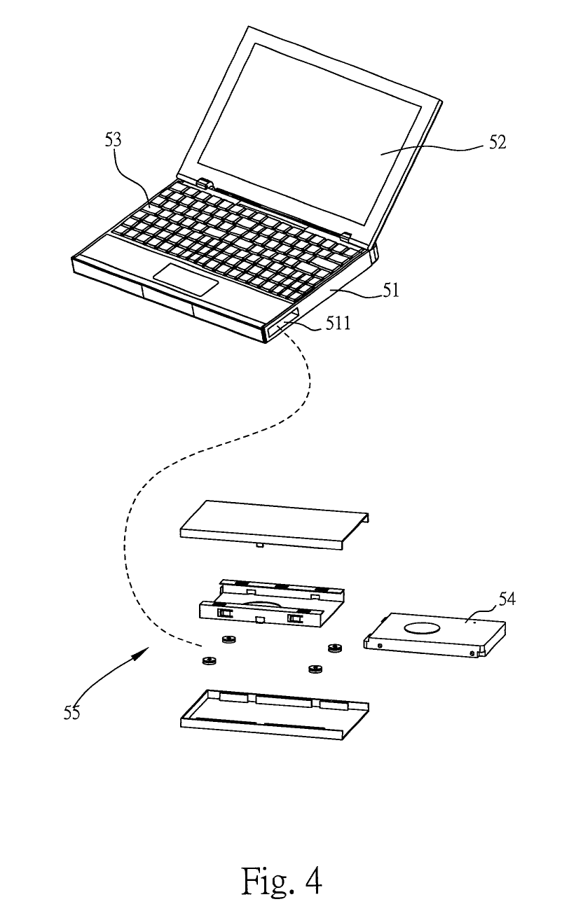

Referring to FIG. 4, a data processing system 5 in one embodiment of the present invention is shown. The data processing system 5 includes a host system 51, a display device 52, an input device 53, a data storage device 54, and a shock absorber module 55. The host system 51 has an accommodation slot 511. The display device 52 and the input device 53 are coupled to the host system 51 respectively. The shock absorber module 55 accommodates the data storage device 54 therein.

In this embodiment, the shock absorber module 55 is preferable the above-mentioned shock absorber module 1 or 3 in FIG. 1 or 2. The data storage device 54 is, for example, a hard disc drive 2 as shown in FIG. 1 or 2. The data storage device 54 is detachably disposed inside the shock absorber module 55, and the shock absorber module 55 is detachably inserted in the accommodation slot 511. In this manner, the shock absorber module 55 is possible to interchangeably share the accommodation slot 511 with other electronic devices, such as CD-ROM, DVD-ROM, or battery. That is, when the shock absorber module 55 is removed from the accommodation slot 511, other electronic devices are possibly installed in the accommodation slot 511.

Although specific embodiments have been illustrated and described, it will be obvious to those skilled in the art that various modifications may be made without departing from what is intended to be limited solely by the appended claims.

What is claimed is:

1. A shock absorber module used in a portable computer, comprising:
a bracket for accommodating an electronic device therein;
at least one shock absorber, connected to a bottom surface of said bracket, for providing said electronic device with shock absorbing capability; and
a modular housing for providing a space to accommodate said bracket and said shock absorber, said modular housing being detachably installed in an accommodation slot of said portable computer.

2. The shock absorber module according to claim 1, wherein said bracket comprises at least one leaf spring for engaging said electronic device with said bracket.

3. The shock absorber module according to claim 2, wherein said bracket is made of metal, and said leaf spring directly contacts a metal housing of said electronic device to provide electromagnetic interference (EMI) shielding.

4. The shock absorber module according to claim 1, wherein said shock absorber is made of rubber.

5. The shock absorber module according to claim 1, wherein said electronic device is a hard disc drive (HDD).

6. A hard disc drive shock absorber module used in a portable computer, comprising:
a bracket for accommodating a hard disc drive therein, said bracket having at least one engaging device for engaging said hard disc drive with said bracket;
a shock absorber, connected to a bottom surface of said bracket, for absorbing impact on said hard disc drive shock absorber module; and
a housing for providing a space to accommodate said bracket and said shock absorber, said housing having a retaining device to restrain movement of said bracket, said housing being detachably installed in an accommodation slot of said portable computer.

7. The hard disc drive shock absorber module according to claim 6, wherein said engaging device is a leaf spring.

8. The hard disc drive shock absorber module according to claim 7, wherein said bracket is made of metal, said leaf spring directly contacts a metal housing of said hard disc drive to provide electromagnetic interference shielding.

9. The hard disc drive shock absorber module according to claim 6, wherein said shock absorber is made of rubber.

10. A data processing system, comprising:
a host system having an accommodation slot;
a display device coupled to said host system;
an input device coupled to said host system;
a data storage device; and
a shock absorber module,
wherein said shock absorber module comprises:
a bracket for accommodating said data storage device therein;
at least one shock absorber, connected to a bottom surface of said bracket, for absorbing impact on said data processing system to protect said data storage device; and
a modular housing for providing a space to accommodate said bracket and said shock absorber, said modular housing being detachably installed in said accommodation slot.

11. The data processing system according to claim 10, wherein said bracket comprises at least one leaf spring for engaging said data storage device with said bracket.

12. The data processing system according to claim 11, wherein said bracket is made of metal, and said leaf spring directly contacts a metal housing of said data storage device to provide electromagnetic interference shielding.

13. The data processing system according to claim 10, wherein said shock absorber is made of rubber.
